(19) United States
(12) Patent Application Publication
(10) Pub. No.: US 2015/0366058 A1
(43) Pub. Date: Dec. 17, 2015

(54) WIRING SUBSTRATE AND METHOD FOR PRODUCING THE SAME

(71) Applicant: NGK SPARK PLUG CO., LTD., Nagoya-shi (JP)

(72) Inventors: Takuya HANDO, Inuyama-shi (JP); Atsuhiko SUGIMOTO, Kakamigahara-shi (JP)

(21) Appl. No.: 14/741,174

(22) Filed: Jun. 16, 2015

(30) Foreign Application Priority Data
Jun. 17, 2014 (JP) 2014-124052
Apr. 13, 2015 (JP) 2015-081404

(51) Int. Cl. H05K 1/11; H05K 3/40; B23K 1/00; H05K 3/36

(52) U.S. Cl. CPC H05K 1/11; H05K 3/368; H05K 3/40; B23K 1/0008

(57) ABSTRACT

A wiring substrate includes a first substrate to be connected to a second substrate. Electrodes are disposed on a substrate main surface of the first substrate, and columnar terminals are bonded onto the electrodes via solder portions. Each columnar terminal includes a columnar terminal body, and a projecting piece that projects from an outer peripheral surface of the columnar terminal body at a center portion, in a height direction, of the outer peripheral surface of the columnar terminal body. Each columnar terminal has a shape vertically symmetrical about the projecting piece.

### CROSS REFERENCE TO RELATED APPLICATIONS

The present application claims priority from Japanese Patent Application No. 2014-124052, which was filed on Jun. 17, 2014, and Japanese Patent Application No. 2015-081404, which was filed on Apr. 13, 2015, the disclosures of which are herein incorporated by reference in their entirety.

### BACKGROUND OF THE INVENTION

1. Field of the Invention

The present invention relates to a wiring substrate including a substrate to be connected to another substrate, and a method for producing the wiring substrate.

2. Description of Related Art

In recent years, with downsizing of electric devices and electronic devices, wiring substrates and the like mounted in these devices are also required to be downsized and highly integrated. As an example of such a wiring substrate, a wiring substrate having a package-on-package (POP) structure obtained by stacking a plurality of substrates (so-called packages) has conventionally been proposed (refer to Patent Documents 1 and 2, for example). A proposed method for connecting such substrates, for example, includes: bonding a plurality of terminals each having a length of 100 μm or less (so-called micro pins) via solder portions onto a plurality of electrodes disposed on a main surface of a lower-side substrate; and connecting front end portions of the terminals to an upper-side substrate. Generally, since a semiconductor integrated circuit device (IC chip) used as, for example, a microprocessor of a computer is mounted on a main surface of a substrate, a gap greater than the height of the IC chip needs to be secured between the upper-side substrate and the lower-side substrate.

### RELATED ART DOCUMENTS

Patent Document 1 is Japanese Patent Application Laid-Open (kokai) No. 2012-9782.

Patent Document 2 is Japanese Patent Application Laid-Open (kokai) No. 2008-159956.

### BRIEF SUMMARY OF THE INVENTION

Incidentally, the above-mentioned bonding of the micro pins needs to be performed by use of a dedicated positioning jig. In detail, first, a lower-side substrate 153 is prepared in which a plurality of electrodes 152 are formed on a substrate main surface 151 and solder paste is applied onto each electrode 152 (refer to FIG. 15). Then, a plurality of micro pins 154 are set in pin insertion holes 156 of a positioning jig 155, and disposed beneath the lower-side substrate 153. Then, a reflow process is performed to heat and melt the solder paste, whereby each micro pin 154 is bonded to its corresponding electrode 152, and stands upright. Thus, a space larger than the height of an IC chip is reliably secured between the upper-side substrate and the lower-side substrate 153 when the front ends of the micro pin 154 are connected to the upper-side substrate.

However, with recent downsizing of wiring substrates, the pitch between adjacent micro pins 154 tends to be narrower. Along with this, the pitch between adjacent pin insertion holes 156 also tends to be narrower. If the pitch becomes, for example, 100 μm or less, it is difficult to fabricate the positioning jig 155. Even if a positioning jig conforming to the pitch of 100 μm or less can be fabricated, it is difficult to perform the reflow process with the micro pins being set in the pin insertion holes. As a result, it becomes difficult to make the micro pins stand upright.

The present invention has been conceived in view of the above problems, and an object of the invention is to provide a wiring substrate which can be easily connected to a second substrate via columnar terminals by making the columnar terminals easily stand upright.

According to one aspect of the invention, a wiring substrate includes a first substrate to be connected to a second substrate (i.e., the first substrate is for connection to a second substrate). The wiring substrate further includes: a plurality of electrodes disposed on a substrate main surface of the first substrate; and a plurality of columnar terminals used for connecting the first substrate to the second substrate (e.g., the columnar terminals are to be solder-bonded to the second substrate), which are bonded onto the plurality of electrodes via solder portions. Each of the columnar terminals includes a columnar terminal body made of a conductive material, and a projecting piece that projects from an outer peripheral surface of the columnar terminal body at a center portion, in a height direction, of the columnar terminal body.

In one embodiment, each of the columnar terminals has a shape vertically symmetrical about the projecting piece.

In the wiring substrates described above, the projecting piece projects from the outer peripheral surface at the center portion, in the height direction, of the columnar terminal (columnar terminal body). Therefore, when the columnar terminals are bonded onto the electrodes, at least a portion of each columnar terminal is immersed into the heated and melted solder portion. Then, due to influence of the surface tension of the liquid-phase solder or the like, the columnar terminal changes its posture to maintain its weight balance. As a result, the columnar terminal stands upright by itself. Moreover, since the projecting piece projects from the outer peripheral surface of the columnar terminal body, the upper end of each liquid-phase solder portion is prevented from extending upward beyond the projecting piece when the columnar terminals are bonded onto the electrodes. As a result, the projecting piece is reliably supported by the solder portion. Further, in the means 1, since the columnar terminal is vertically symmetrical about the projecting piece, the weight balance of the columnar terminal is improved. The above configuration makes the columnar terminal stand upright more easily. That is, even when the pitch of the adjacent terminals is reduced along with downsizing of the wiring substrate, since the columnar terminals that are easy to stand upright are used as terminals, it is possible to obtain a wiring substrate that can be easily connected to the second substrate via the columnar terminals.

The material used to form the first substrate and the second substrate is not particularly limited, and any material may be used. However, a resin substrate is preferably used, for example. Preferred examples of the resin substrate include substrates made of epoxy resin, polyimide resin, bismaleimide-triazine resin, polyphenylene ether resin, and the like. Besides, a substrate made of a composite material consisting of any one of these resins and glass fiber (glass woven fabric or glass nonwoven fabric) may be used. As other materials, various kinds of ceramics may be selected, for example. Although the configurations of the first substrate and the second substrate are not particularly limited, a build-up multilayer substrate having build-up layer(s) on one or both surfaces of a core substrate or a coreless substrate having no core substrate, may be adopted, for example.

The plurality of electrodes are disposed on the substrate main surface of the first substrate. The plurality of electrodes may be present on only the substrate main surface, or may be present on both the substrate main surface and the substrate rear surface. The plurality of electrodes can be formed of a metal material having conductivity, for example. Examples of the metal material used to form the electrodes include copper, silver, iron, cobalt, nickel, and the like. In particular, the electrodes are preferably made of copper which has high conductivity and is inexpensive. In addition, the electrodes are preferably formed by plating. Thereby, the plurality of electrodes can be formed with high precision and uniform dimension. If printing of a metal paste is used to form the electrodes, it is difficult to form the electrodes with high precision and uniform dimension, which might cause variations in the heights of the individual electrodes.

Further, the plurality of columnar terminals used for connection to the second substrate are bonded onto the plurality of electrodes via the solder portions. Each columnar terminal includes the columnar terminal body made of a conductive material, and the projecting piece that projects from the outer peripheral surface of the columnar terminal body at the center portion, in the height direction, of the outer peripheral surface of the columnar terminal body. The shape of the columnar terminal body is not particularly limited, and may be any shape. However, the end surface (upper end surface/lower end surface), in the height direction, of the columnar terminal body is preferably a flat surface. Thereby, the end surface of the columnar terminal body becomes in conformity with the surface of the electrode, and the gap between the end surface of the columnar terminal body and the surface of the electrode can be reduced when the columnar terminal is bonded onto the electrode via the solder portion. As a result, rattling of the columnar terminal is reduced, which allows the columnar terminal to stand upright more reliably.

Examples of the conductive material used to form the columnar terminal body include copper, silver, iron, cobalt, nickel, and the like. In particular, the columnar terminal body is preferably formed of copper. Thereby, reduction in resistance of the columnar terminal body is achieved, and the conductivity of the columnar terminal body is improved, as compared with a case where the columnar terminal body is formed of the material other than copper. That is, by providing the columnar terminals suitable for connection with the electrodes, the reliability of the wiring substrate can be improved.

The height of the columnar terminal body is not particularly limited, and the columnar terminal body may have any height. For example, the height of the columnar terminal body is preferably 1.0 times or more and 3.0 times or less the outer diameter of the columnar terminal body. If the height of the columnar terminal body is smaller than 1.0 times the outer diameter of the columnar terminal body, the columnar terminal easily stands upright without the projecting piece, and therefore, the problem to be solved by the present invention, that is, “difficulty in making the terminals stand upright”, may not occur. On the other hand, if the height of the columnar terminal body exceeds 3.0 times the outer diameter of the columnar terminal body, it becomes difficult to make the columnar terminal stand upright even when the columnar terminal is provided with the projecting piece.

The projecting piece may be formed integrally with the columnar terminal body at the outer peripheral surface of the columnar terminal body. In this case, the strength of the columnar terminal is increased as compared with a case where the projecting piece is formed as a component separable from the columnar terminal body. Further, the projecting piece may be provided over the entire circumference of the outer peripheral surface of the columnar terminal body. In this case, the upper end of each liquid-phase solder portion is more reliably prevented from extending upward beyond the projecting piece when the columnar terminals are bonded onto the electrodes. Thus, the projecting piece is more reliably supported by the solder portion. As a result, the columnar terminal can stand upright more reliably. Therefore, the wiring substrate capable of securing a gap between the first substrate and the second substrate can be obtained more reliably.

The solder material used to form the solder portion is not particularly limited. Examples of the solder material include Pb—Sn based solder such as 90Pb-10Sn, 95Pb-5Sn, or 40Pb-60Sn, Sn—Sb based solder, Sn—Ag based solder, Sn—Ag—Cu based solder, Au—Ge based solder, Au—Sn based solder, Au—Si based solder, and the like. In particular, the solder portion is preferably formed of lead-free solder. In this case, since the solder portion is free from lead, burden of the wiring substrate on the environment can be reduced.

According to another aspect of the invention, a method of manufacturing the wiring substrate described above includes: a substrate preparation step of preparing the first substrate having the plurality of electrodes disposed on the substrate main surface; a solder paste supplying step of supplying a solder paste onto the plurality of electrodes; a columnar terminal arrangement step of arranging the columnar terminals on the electrodes to which the solder paste has been supplied; and a reflow step of heating and melting the solder paste to immerse at least a portion of each columnar terminal into the solder paste, and to make each columnar terminal stand upright.

According to the above-described wiring substrate manufacturing method, each of the columnar terminals disposed on the electrodes in the columnar terminal arrangement step has the projecting piece projecting from the outer peripheral surface of the columnar terminal body at the center portion thereof in the height direction. Therefore, when at least a portion of each columnar terminal is immersed into the heated and melted solder paste in the reflow process, the columnar terminal changes its posture to maintain its weight balance, due to influence of the surface tension of the liquid-phase solder or the like. As a result, the columnar terminal stands upright by itself. Moreover, since the projecting piece projects from the outer peripheral surface of the columnar terminal body, the liquid-phase solder paste is prevented from extending upward beyond the projecting piece. As a result, the projecting piece is reliably supported by the solder paste. Further, when the columnar terminal has a shape vertically symmetrical about the projecting piece, the weight balance of the columnar terminal is improved. The above configuration makes the columnar terminal stand upright more easily. That is, even when the pitch of the adjacent terminals is reduced along with downsizing of the wiring substrate, since the reflow process makes each columnar terminal stand upright by itself, it is possible to obtain a wiring substrate that can be easily connected to the second substrate via the columnar terminals.

Hereinafter, the wiring substrate manufacturing method will be described.

First, the substrate preparation step is performed to prepare the first substrate having the main surface on which the plurality of electrodes are disposed. In the subsequent solder paste supplying step, solder paste is supplied onto the plurality of electrodes.

When the substrate main surface is covered with a solder resist layer and the plurality of electrodes are exposed through openings penetrating the solder resist layer in its thickness direction, the solder paste is preferably supplied into the openings in the solder paste supplying step. Thereby, the solder paste can be reliably supplied onto the electrodes, which makes manufacturing of the wiring substrate easy. The solder resist layer may be appropriately selected considering insulation property, heat resistance, humidity resistance, and similar property. Preferred examples of the resin material used to form the solder resist layer include epoxy resin, phenolic resin, urethane resin, silicone resin, polyimide resin, and the like.

In the subsequent columnar terminal arrangement step, the columnar terminals are disposed on the electrodes to which the solder paste is supplied. In the subsequent reflow process, the solder paste is heated and melted to immerse at least a portion of each columnar terminal into the solder paste, and to make each columnar terminal stand upright. Through the above process, the wiring substrate is manufactured.

### BRIEF DESCRIPTION OF THE DRAWINGS

Illustrative aspects of the invention will be described in detail with reference to the following figures wherein:

FIG. 1 is a schematic cross-sectional view showing a configuration of a wiring substrate according to an embodiment.

FIG. 2 is a cross-sectional view of a major part of a first substrate.

FIG. 3 is a top view of a columnar terminal.

FIG. 4 is a view showing a columnar member preparation step.

FIG. 5 is a view showing a projecting piece formation process.

FIG. 6 is a view showing a step of forming a base composed of a support substrate and a base resin insulation layer.

FIG. 7 is a view showing a step of forming a conductive layer on the resin insulation layer.

FIG. 8 is a view showing a step of forming a build-up structure.

FIG. 9 is a view showing a step of separating the build-up structure from the support substrate.

FIG. 10 is a view showing a step of forming electrodes on a substrate rear surface of the resin insulation layer.

FIG. 11 is a view showing a solder paste supplying step.

FIG. 12 is a view showing a columnar terminal arrangement step.

FIG. 13 is a top view of a columnar terminal according to another embodiment.

FIG. 14 is a cross-sectional view of a columnar terminal according to another embodiment.

FIG. 15 is a view showing a method of manufacturing a wiring substrate according to a conventional art.

### DETAILED DESCRIPTION OF EXEMPLARY EMBODIMENTS OF THE INVENTION

Hereinafter, one specific embodiment of the present invention will be described in detail with reference to the drawings.

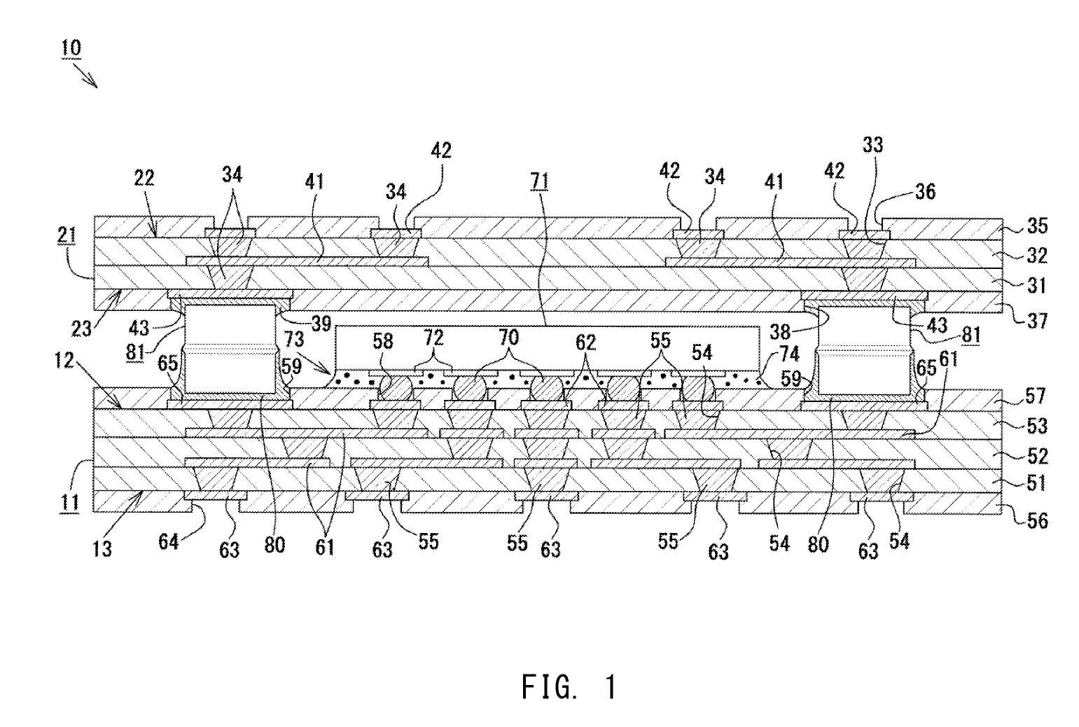

FIG. 1 is a schematic cross-sectional view of a wiring substrate 10 according to the present embodiment. The wiring substrate 10 includes a first substrate 11 and a second substrate 21.

The second substrate 21 is a substrate having a structure in which two resin insulation layers 31 and 32 made of epoxy resin and conductive layers 41 made of copper are alternately stacked. Each of the resin insulation layers 31 and 32 has via holes 33 and via conductors 34. Each via hole 33 has a truncated cone shape. The via holes 33 are formed by subjecting the resin insulation layers 31 and 32 to drilling with a YAG laser or a carbon dioxide gas laser. The via conductors 34 are conductors whose diameters are expanded in the same direction (upward direction in FIG. 1).

On a substrate main surface 22 of the second substrate 21 (on a surface of the second resin insulation layer 32), main-surface-side electrodes 42 (15 μm thick) electrically connected to the conductive layers 41 through the via conductors 34 are formed in an array pattern. Further, almost the entire surface of the second resin insulation layer 32 is covered with a solder resist layer 35 made of epoxy resin and having a thickness of about 30 μm. At predetermined positions of the solder resist layer 35, openings 36 are formed penetrating the solder resist layer 35 in its thickness direction so that the main-surface-side electrodes 42 are exposed through the openings 36.

On the other hand, on a substrate rear surface 23 of the second substrate 21 (on a lower surface of the first resin insulation layer 31), rear-surface-side electrodes 43 (15 μm thick) electrically connected to the conductive layers 41 through the via conductors 34 are disposed at a plurality of positions. Further, almost the entire lower surface of the first resin insulation layer 31 is covered with a solder resist layer 37 made of epoxy resin and having a thickness of about 30 μm. At predetermined positions of the solder resist layer 37, openings 38 are formed penetrating the solder resist layer 37 in its thickness direction so that the rear-surface-side electrodes 43 are exposed through the openings 38. Solder portions 39 are formed on the rear-surface-side electrodes 43 exposed through the openings 38.

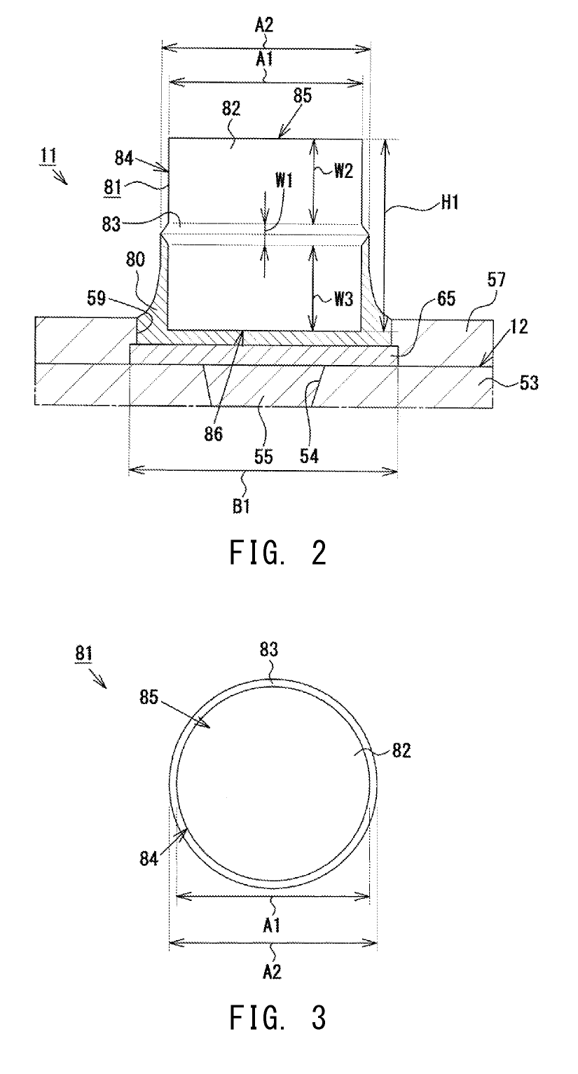

As shown in FIGS. 1 and 2, the first substrate 11 is connected to the above-mentioned second substrate 21, and has a structure similar to the second substrate 21. That is, the first substrate 11 is a substrate having a structure in which three resin insulation layers 51, 52, and 53 made of epoxy resin and conductive layers 61 made of copper are alternately stacked. Each of the resin insulation layers 51 to 53 has via holes 54 and via conductors 55. Each via hole 54 has a truncated cone shape. The via holes 54 are formed by subjecting the resin insulation layers 51 to 53 to drilling with a YAG laser or a carbon dioxide gas laser. The via conductors 55 are conductors whose diameters are expanded in the same direction (upward direction in FIG. 1), and connect the conductive layers 61 electrically to each other.

As shown in FIG. 1, on a substrate rear surface 13 of the first substrate 11 (on a lower surface of the first resin insulation layer 51), rear-surface-side electrodes 63 (15 μm thick) electrically connected to the conductive layers 61 through the via conductors 55 are disposed at a plurality of positions. Further, almost the entire lower surface of the first resin insulation layer 51 is covered with a solder resist layer 56 made of epoxy resin and having a thickness of about 30 μm. At predetermined positions of the solder resist layer 56, openings 64 are formed penetrating the solder resist layer 56 in its thickness direction so that the rear-surface-side electrodes 63 are exposed through the openings 64. On the surfaces of the rear-surface-side electrodes 63, a plurality of solder bumps (not shown) electrically connectable to a motherboard (not shown) are disposed. The first substrate 11 is mounted on the motherboard through the solder bumps.

On the other hand, as shown in FIG. 1, on a substrate main surface 12 of the first substrate 11 (on the surface of the third resin insulation layer 53), main-surface-side electrodes 62 electrically connected to the conductive layers 61 through the via conductors 55 are formed in an array pattern. Almost the entire surface of the third resin insulation layer 53 (substrate main surface 12) is covered with a solder resist layer 57 made of epoxy resin and having a thickness of about 30 μm. At predetermined positions of the solder resist layer 57, openings 58 are formed penetrating the solder resist layer 57 in its thickness direction so that the main-surface-side electrodes 62 are exposed through the openings 58. The main-surface-side electrodes 62 are connected to connection terminals 72 disposed on a bottom surface of an IC chip 71 having a rectangular plate shape, through solder bumps 70. That is, the solder bumps 70 are so-called C4 bumps used for flip-chip connection with the connection terminals 72. A region having the main-surface-side electrodes 62 is an IC chip mount region 73 in which the IC chip 71 is mountable.

As shown in FIG. 1, a gap between the solder resist layer 57 and the IC chip 71 is filled with an underfill 74. As a result, the first substrate 11 and the IC chip 71 are fixed to each other with the gap therebetween being sealed. The underfill 74 of the present embodiment is made of epoxy resin having a thermal expansion coefficient of about 20 to 60 ppm/° C. (specifically, 34 ppm/° C.).

Further, as shown in FIGS. 1 and 2, on the substrate main surface 12 of the first substrate 11, main-surface-side electrodes 65 electrically connected to the conductive layers 61 through the via conductors 55 are disposed at a plurality of positions. As shown in FIG. 2, each main-surface-side electrode 65 has a circular shape in the plan view, and has an outer diameter B1 set to 100 μm and a thickness set to 15 μm. The outer diameter B1 is set to be larger than an outer diameter (30 μm) of an upper end of the via conductor 55. At predetermined positions of the solder resist layer 57, openings 59 are formed penetrating the solder resist layer 57 in its thickness direction so that the main-surface-side electrodes 65 are exposed through the openings 59. In the present embodiment, an inner diameter of each opening 59 is set to 95 μm.

A plurality of columnar terminals 81 used for electrical connection with the second substrate 21 are bonded onto the main-surface-side electrodes 65 through solder portions 80. Specifically, a lower end portion of each columnar terminal 81 is bonded to the main-surface-side electrode 65 through the solder portion 80, and an upper end portion of the columnar terminal 81 is bonded to the rear-surface-side electrode 43 of the second substrate 21 via the solder portion 39. Each columnar terminal 81 is soldered by use of a solder having a melting point higher than that of the solder bump 70 used for mounting the IC chip 71. Specifically, as the solder portions 39 and 80 of the present embodiment, an Sn—Ag—Cu based solder is used as a solder material.

As shown in FIGS. 1 to 3, each columnar terminal 81 includes a columnar terminal body 82 having a cylindrical shape, and a projecting piece 83 having an annular shape. The columnar terminal body 82 is made of copper as a conductive material, and the surface thereof is covered with a nickel layer and a gold layer. The nickel layer is a plated layer formed by subjecting the surface of the columnar terminal body 82 to electroless nickel plating. The gold layer is a plated layer formed by electroless gold plating so as to cover the nickel layer.

Further, as shown in FIGS. 2 and 3, an outer diameter A1 of the columnar terminal body 82 is set to 45 μm, and a height H1 of the columnar terminal body 82 is set to 90 μm. That is, in the present embodiment, a micro pin having a height H1 (length) of 100 μm or less is used as the columnar terminal 81. The height H1 of the columnar terminal body 82 is set to be 2.0 times the outer diameter A1 of the columnar terminal body 82. In other words, the ratio between the height H1 of the columnar terminal body 82 and the outer diameter A1 thereof is set to 2:1. The height H1 of the columnar terminal body 82 is smaller than the inner diameter (95 μm) of each opening 59 of the solder resist layer 57.

On the other hand, the projecting piece 83 is formed integrally with the columnar terminal body 82 at an outer peripheral surface 84 of the columnar terminal body 82. That is, the projecting piece 83 is made of the same material (copper) as the material used for the columnar terminal body 82, and the surface thereof is covered with the nickel layer and the gold layer. The projecting piece 83 extends along a circumferential direction of the columnar terminal body 82 at a center portion, in a height direction, of the columnar terminal body 82. The projecting piece 83 is provided over the entire circumference of the outer peripheral surface 84 of the columnar terminal body 82. In the present embodiment, a width W1 of the projecting piece 83 is set to 10 μm. Further, in the present embodiment, a width W2 of the outer peripheral surface 84 exposed in an upper region relative to the projecting piece 83 is set to 40 μm, and a width W3 of the outer peripheral surface 84 exposed in a lower region relative to the projecting piece 83 is also set to 40 μm. Therefore, the columnar terminal 81 has a shape vertically symmetrical about the projecting piece 83. In the outer peripheral surface 84, the area of the region where the projecting piece 83 is not formed is larger than the area of the region where the projecting piece 83 is formed.

As shown in FIG. 2, the width of the projecting piece 83 is reduced outward in the radial direction of the columnar terminal body 82. That is, the width W1 of the projecting piece 83 indicates the maximum width of the projecting piece 83 (specifically, the width at a portion thereof connected to the columnar terminal body 82). A front end portion of the projecting piece 83 has a curved surface. Further, a connection portion between the projecting piece 83 and the columnar terminal body 82 also has a curved surface.

As shown in FIGS. 2 and 3, the projecting piece 83 projects from the outer peripheral surface 84 of the columnar terminal body 82. The amount of projection of the projecting piece 83 from the outer peripheral surface 84 is set to 5 μm in the present embodiment. An outer diameter A2 of the projecting piece 83 is set to be larger than the outer diameter A1 (45 μm) of the columnar terminal body 82, and it is 55 μm in the present embodiment. The outer diameter A2 is the maximum diameter of the columnar terminal 81. The outer diameter A2 of the projecting piece 83 is smaller than the outer diameter B1 (100 μm) that is the maximum diameter of the main-surface-side electrode 65. The inner diameter (about 95 μm) of the opening 59 of the solder resist layer 57 is larger than the maximum diameter (55 μm) of the columnar terminal 81.

As shown in FIGS. 1 and 2, the columnar terminal 81 is bonded onto the main-surface-side electrode 65 through the solder portion 80, with the lower end portion thereof being inserted into the solder portion 80. A lower end surface 86 of the columnar terminal body 82 is a flat surface that is arranged in parallel to the surface of the main-surface-side electrode 65 while being apart from the surface of the main-surface-side electrode 65. The distance between the lower end surface 86 and the surface of the main-surface-side electrode 65 is set to 20 μm in the present embodiment. The solder portion 80 convers the entirety of the surface portion of the main-surface-side electrode 65 exposed through the opening 59. Along with that, the solder portion 80 covers the entirety of the lower end surface 86 of the columnar terminal body 82, the entirety of the outer peripheral surface 84 exposed in the lower region relative to the projecting piece 83, and a lower side surface of the projecting piece 83 (a surface thereof on the main-surface-side electrode 65 side). That is, the solder portion 80 projects upward from the main-surface-side electrode 65, and an upper end thereof extends to the projecting piece 83.

As shown in FIG. 1, the columnar terminal 81 is bonded onto the rear-surface-side electrode 43 through the solder portion 39, with the upper end portion thereof being inserted into the solder portion 39. An upper end surface 85 of the columnar terminal body 82 is a flat surface that is arranged in parallel to the surface of the rear-surface-side electrode 43 while being apart from the surface (lower surface) of the rear-surface-side electrode 43. The distance between the upper end surface 85 and the surface of the rear-surface-side electrode 43 is set to 20 μm in the present embodiment. The solder portion 39 covers the entirety of the surface portion of the rear-surface-side electrode 43 exposed through the opening 38. Along with that, the solder portion 39 covers the entirety of the upper end surface 85 of the columnar terminal body 82, and a portion of the outer peripheral surface 84 exposed in the upper region relative to the projecting piece 83.

Next, a method of manufacturing the wiring substrate 10 will be described.

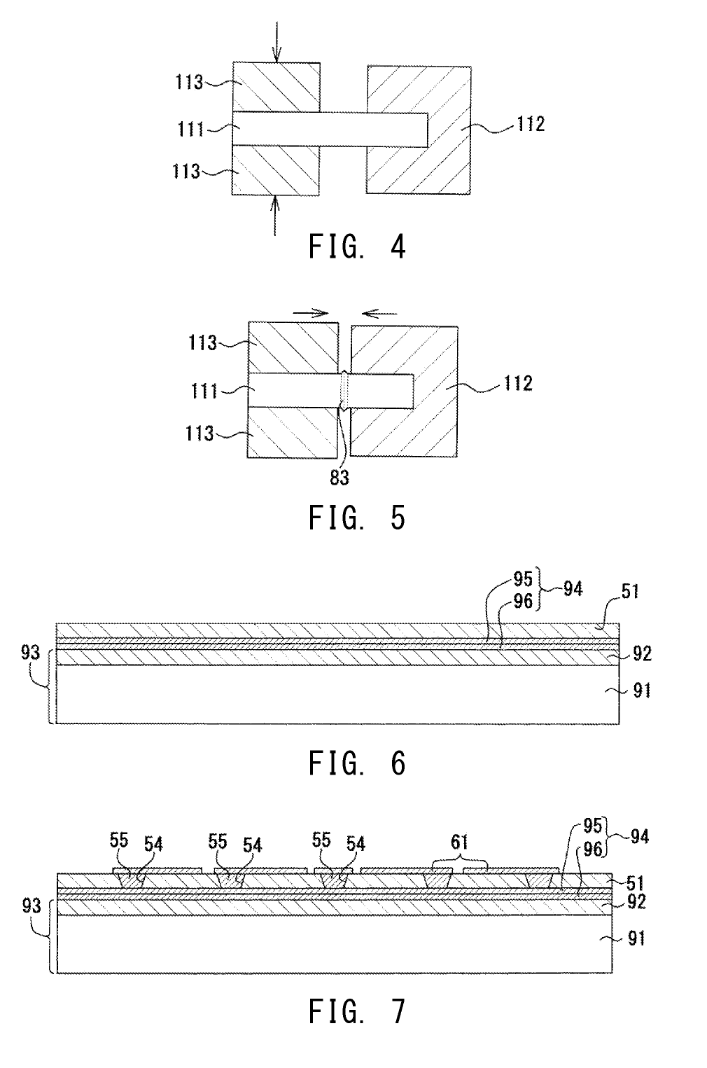

First, the columnar terminals 81 are fabricated. Specifically, in a columnar member preparation step, columnar members 111 (refer to FIG. 4) made of copper as a conductive material are prepared in advance. A first end portion (a right end portion in FIG. 4) of each columnar member 111 is held by a first chuck 112, while a second end portion (a left end portion in FIG. 4) of the columnar member 111 is held by a second chuck 113.

In a subsequent projecting piece formation step, the first chuck 112 and the second chuck 113 are moved so that they come closer to each other, thereby compressing the columnar member 111 in its axial direction (refer to FIG. 5). As a result, the projecting piece 83 projects from the outer peripheral surface 84 of the columnar member 111. Thereafter, residual portions at both ends of the columnar member 111 are cut off to complete the columnar terminal 81.

In a substrate preparation step, an intermediate product of the first substrate 11 is prepared in advance. The intermediate product of the first substrate 11 has a structure in which a plurality of product portions each to be the first substrate 11 are arrayed along the planar direction. The intermediate product of the first substrate 11 is fabricated as follows. First, a support substrate 91, such as a glass epoxy substrate, having a sufficient strength is prepared (refer to FIG. 6). Next, a sheet-shaped insulating resin base material made of epoxy resin, which is in a half-cured state, is bonded onto the support substrate 91 to form a base resin insulation layer 92, thereby yielding a base 93 composed of the support substrate 91 and the base resin insulation layer 92 (refer to FIG. 6). Then, on one side of the base 93 (specifically, an upper surface of the base resin insulation layer 92), a build-up metal sheet member 94 is disposed (refer to FIG. 6). Since the build-up metal sheet member 94 is disposed on the semi-cured base resin insulation layer 92, adherence enough to prevent the build-up metal sheet member 94 from coming off from the base resin insulation layer 92 in the subsequent manufacturing process is ensured. The build-up metal sheet member 94 is composed of two copper foils 95 and 96 that are adhered so as to be strippable from each other. Specifically, the build-up metal sheet member 94 is formed by stacking the copper foils 95 and 96 through metal plating (e.g., chrome plating).

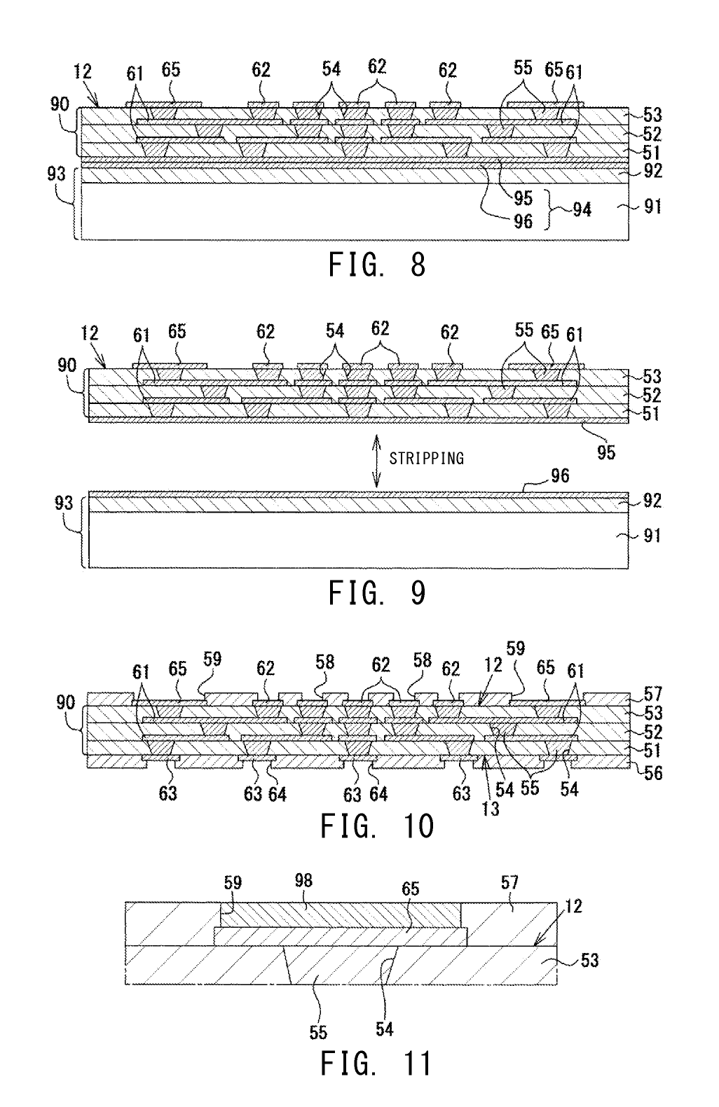

Thereafter, the sheet-shaped insulating resin base material is stacked on the build-up metal sheet member 94, and the resultant structure is subjected to heating and pressurization under vacuum by use of a vacuum thermocompression press (not shown) to cure the insulating resin base material, thereby forming the first resin insulation layer 51 (refer to FIG. 6). Then, the via holes 54 are formed at predetermined positions in the first resin insulation layer 51 by laser machining, followed by a desmearing step for removing smears in the via holes 54. Thereafter, electroless copper plating and copper electroplating are performed according to a known technique to form the via conductors 55 in the via holes 54. Further, etching is performed according to a known technique (e.g., semi-additive technique) to form the conductive layer 61 in a predetermined pattern on the first resin insulation layer 51 (see FIG. 7). Also, the second and third resin insulation layers 52 and 53 and the corresponding conductive layers 61 are formed and stacked on the first resin insulation layer 51 according to a technique similar to that for the first resin insulation layer 51 and the corresponding conductive layer 61. Through the above-mentioned manufacturing process, the build-up metal sheet member 94 and a build-up structure 90 in which the resin insulation layers 51 to 53 and the conductive layers 61 are stacked, are formed on the support substrate 91 (refer to FIG. 8).

Next, the uppermost resin insulation layer 53 is subjected to plating to form the main-surface-side electrodes 62 and 65 on the substrate main surface 12 (refer to FIG. 8). In the present embodiment, the main-surface-side electrodes 62 and 65 are formed in a predetermined pattern on the third resin insulation layer 53 by a semi-additive technique. Specifically, first, the via holes 54 are formed at predetermined positions in the resin insulation layer 53 by laser machining, followed by a desmearing step for removing smears in the via holes 54. After the surface of the third resin insulation layer 53 is subjected to electroless copper plating, a dry film is laminated on the third resin insulation layer 53 to form a plating resist (not shown). Then, the plating resist is subjected to laser machining by use of a laser machining device. As a result, at positions corresponding to the via holes 54 of the third resin insulation layer 53, openings are formed, each having an inner diameter set to be larger than the outer diameter of the via hole 54 at its upper end. Then, copper electroplating is performed to form the via conductors 55 in the via holes 54, and form the main-surface-side electrodes 62 and 65 mainly made of copper on the upper surface of the third resin insulation layer 53 (substrate main surface 12) exposed through the openings and on the upper surfaces of the via conductors 55 exposed through the openings. Thereafter, the plating resist is stripped off, and unnecessary electroless plated layer is removed.

Next, the base 93 is removed to expose the copper foil 95. Specifically, the two copper foils 95 and 96 forming the build-up metal sheet member 94 are stripped from each other at the interface between them to remove the build-up structure 90 from the support substrate 91 (refer to FIG. 9). Then, the copper foil 95 on the substrate rear surface 13 (lower surface) is patterned by etching to form the rear-surface-side electrodes 63 in regions of the first resin insulation layer 51 on the substrate rear surface 13 (refer to FIG. 10). Thereafter, photosensitive epoxy resin is applied onto the first resin insulation layer 51 having the rear-surface-side electrodes 63, and cured, thereby forming the solder resist layer 56 so as to cover the substrate rear surface 13 (refer to FIG. 10). Next, exposure and development are performed with a predetermined mask pattern being disposed on the solder resist layer 56 to pattern the openings 64 in the solder resist layer 56.

Further, photosensitive epoxy resin is applied onto the third resin insulation layer 53 having the main-surface-side electrodes 62, and cured, thereby forming the solder resist layer 57 so as to cover the substrate main surface 12 (refer to FIG. 10). Next, exposure and development are performed with a predetermined mask pattern being disposed on the solder resist layer 57 to pattern the openings 58 and 59 in the solder resist layer 57 (refer to FIG. 10).

Further, a metal mask (not shown) is disposed on the substrate main surface 12 (specifically, on the surface of the solder resist layer 57). The metal mask disposed on the substrate main surface 12 has previously been subjected to drilling or the like to form openings. As a result, at positions corresponding to the openings 58 of the solder resist layer 57, a plurality of openings are formed through which the main-surface-side electrodes 62 are exposed.

Next, solder is printed onto the openings of the metal mask. Specifically, solder paste is printed onto the main-surface-side electrodes 62 exposed through the openings. Next, the build-up structure 90 on which the solder paste is printed is placed in a reflow furnace, and heated to a temperature 10° C. to 40° C. higher than the melting point of the solder. At this time, the solder paste is melted, and the hemispherically protruding solder bumps 70 are formed in the openings. Thereafter, the metal mask is removed. At this time, the intermediate product of the first substrate 11 is completed. Further, the intermediate product of the first substrate 11 is divided into pieces by use of a known cutting device or the like. As a result, the product portions are separated from each other, thereby yielding a lot of first substrates 11 as individual products at the same time.

Thereafter, the IC chip 71 is mounted on the IC chip mount region 73 of the first substrate 11. At this time, the connection terminals 72 disposed on the bottom surface side of the IC chip 71 are mounted on the solder bumps 70 disposed on the first substrate 11 side. Then, the first substrate 11 with the IC chip 71 is heated to a temperature of about 230° C. to 260° C. to heat and melt (reflow) the solder bumps 70, whereby the main-surface-side electrodes 62 are flip-chip-connected to the connection terminals 72, and thus the IC chip 71 is mounted on the first substrate 11. Further, the gap between the substrate main surface 12 of the first substrate 11 and the IC chip 71 is filled with the underfill 74, followed by curing. Thus, the gap is sealed with resin.

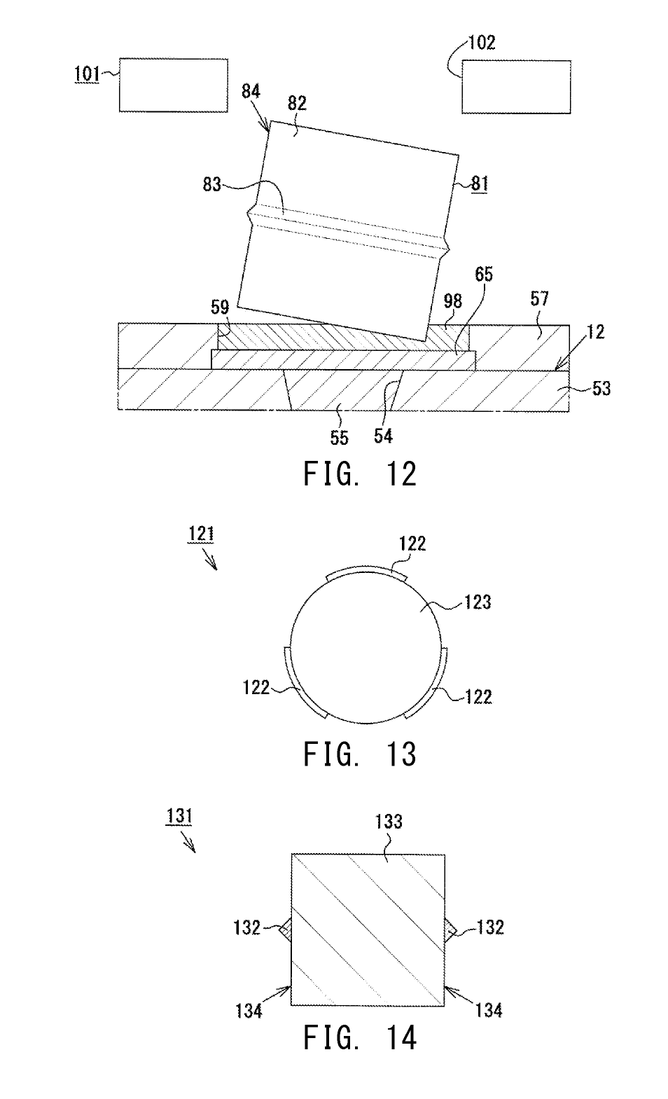

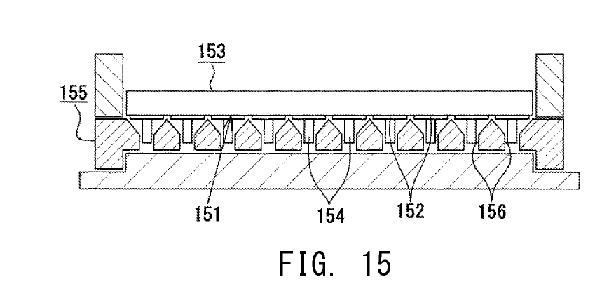

Next, a solder paste supplying step is performed. Specifically, first, a metal mask (not shown) is disposed on the substrate main surface 12 (specifically, on the surface of the solder resist layer 57). The metal mask disposed on the substrate main surface 12 has previously been subjected to drilling or the like to form openings. Therefore, at positions corresponding to the openings 59 of the solder resist layer 57, a plurality of openings are formed, through which the main-surface-side electrodes 65 are exposed. Next, a solder paste 98 is supplied onto the main-surface-side electrodes 65 exposed in the openings of the metal mask and the openings 59 of the solder resist layer 57 (refer to FIG. 11). In the solder paste supplying step of the present embodiment, the solder paste 98 is supplied by a printing technique. Thereafter, the metal mask is removed.

In a subsequent columnar terminal arrangement step, the columnar terminals 81 are disposed on the main-surface-side electrodes 65 onto which the solder paste 98 is supplied. Specifically, first, a positioning jig 101 used for positioning of the plurality of columnar terminals 81 is prepared (refer to FIG. 12). Next, the respective columnar terminals 81 are inserted into a plurality of columnar terminal insertion holes 102 provided in the positioning jig 101, thereby disposing the columnar terminals 81 on the solder paste 98. The columnar terminal insertion holes 102 of the present embodiment are formed in the same cross-sectional shape, and each hole 102 has a diameter enough to accommodate the entirety of each columnar terminal 81 regardless of the orientation of the columnar terminal 81. The positioning jig 101 is preferably formed of a metal material having a high mechanical strength. For example, the positioning jig 101 is formed of an alloy composed of tungsten (W), carbon (C), and cobalt (Co).

In a subsequent reflow step, the solder paste 98 is melted by heating, whereby a portion of each columnar terminal 81 is immersed into the solder paste 98, and the columnar terminal 81 is made to stand upright. Specifically, in the state where each columnar terminal 81 is in contact with the solder paste 98, the structure is heated to a temperature 10° C. to 40° C. higher than the melting point of the solder to heat and melt (reflow) the solder paste 98. At this time, the lower end portion of the columnar terminal 81 is immersed in the solder paste 98 (refer to FIG. 12). Then, due to influences of surface tension of the liquid-phase solder and buoyancy that occurs in the projecting piece 83, the columnar terminal 81 floats, and the columnar terminal 81 changes its posture to maintain its weight balance. As a result, the columnar terminal 81 stands upright by itself. In addition, the liquid-phase solder paste 98 does not flow beyond the projecting piece 83 but stays on the main-surface-side electrode 65 side, which makes the columnar terminal 81 stand upright more easily. As a result, the plurality of columnar terminals 81 are solder-bonded to the plurality of main-surface-side electrodes 65 at the same time (refer to FIG. 2).

Further, an intermediate product of the second substrate 21 is prepared in advance through a technique similar to that for the intermediate product of the first substrate 11 described above. The intermediate product of the second substrate 21 has a structure in which a plurality of product portions each to be the second substrate 21 are arrayed along the planar direction. The intermediate product of the second substrate 21 is fabricated as follows. First, a base similar to the base 93 (refer to FIG. 6) is prepared. Next, on one side of the base, a build-up metal sheet member similar to the build-up metal sheet member 94 (refer to FIG. 6) is disposed.

Thereafter, a sheet-shaped insulating resin base material is stacked on the build-up metal sheet member, and the resultant structure is subjected to heating and pressurization under vacuum by use of a vacuum thermocompression press (not shown) to cure the insulating resin base material, thereby forming the first resin insulation layer 31. Then, the via holes 33 are formed at predetermined positions in the first resin insulation layer 31 by laser machining, followed by a desmearing step for removing smears in the via holes 33. Thereafter, electroless copper plating and copper electroplating are performed according to a known technique to form the via conductors 34 in the via holes 33. Further, etching is performed according to a known technique (e.g., semi-additive technique) to form the conductive layer 41 in a predetermined pattern on the first resin insulation layer 31. Further, the second resin insulation layer 32 is formed according to a technique similar to that for the first resin insulation layer 31 described above, and stacked on the first resin insulation layer 31. Through the above-mentioned manufacturing process, the build-up metal sheet member and a build-up structure in which the resin insulation layers 31 and 32 and the corresponding conductive layers 41 are stacked, are formed on the base.

Next, the uppermost resin insulation layer 32 is subjected to plating to form the main-surface-side electrodes 42 on the substrate main surface 22. In the present embodiment, the main-surface-side electrodes 42 are formed in a predetermined pattern on the second resin insulation layer 32 by a semi-additive technique.

Next, the build-up structure is removed from the base by stripping the two copper foils forming the build-up metal sheet member from each other at the interface between them. Then, the copper foil on the substrate rear surface 23 (lower surface) is patterned by etching, thereby forming the rear-surface-side electrodes 43 in regions of the first resin insulation layer 31 on the substrate rear surface 23.

Thereafter, photosensitive epoxy resin is applied onto the second resin insulation layer 32 having the main-surface-side electrodes 42, and cured, thereby forming the solder resist layer 35 so as to cover the substrate main surface 22. Next, exposure and development are performed with a predetermined mask being disposed on the solder resist layer 35 to pattern the openings 36 in the solder resist layer 35. Further, photosensitive epoxy resin is applied onto the first resin insulation layer 31 having the rear-surface-side electrodes 43, and cured, thereby forming the solder resist layer 37 so as to cover the substrate rear surface 23. Next, exposure and development are performed with a predetermined mask being disposed on the solder resist layer 37 to pattern the openings 38 in the solder resist layer 37.

Next, a metal mask (not shown) is disposed on the substrate rear surface 23 (specifically, on the surface of the solder resist layer 37). The metal mask disposed on the substrate rear surface 23 has previously been subjected to drilling or the like to form openings. Therefore, at positions corresponding to the openings 38 of the solder resist layer 37, a plurality of openings through which the rear-surface-side electrodes 43 are exposed are formed. Further, solder paste is printed onto the rear-surface-side electrodes 43 exposed through the openings of the metal mask and the openings 38 of the solder resist layer 37, thereby forming the solder portions 39. Thereafter, the metal mask is removed. At this time, the intermediate product of the second substrate 21 is completed. Further, the intermediate product of the second substrate 21 is divided into pieces by use of a known cutting device or the like. As a result, the product portions are separated from each other, thereby yielding a lot of second substrates 21 as individual products at the same time.

Next, the second substrate 21 is connected to the first substrate 11. Specifically, the upper end portions of the columnar terminals 81 disposed on the substrate main surface 12 side of the first substrate 11 are brought into contact with the solder portions 39 disposed on the substrate rear surface 23 side of the second substrate 21. In this state, the solder portions 39 are heated to a temperature 10° C. to 40° C. higher than the melting point of the solder to melt (reflow) the solder portions 39, whereby the upper end portions of the columnar terminals 81 are immersed into the solder portion 39. As a result, the plurality of columnar terminals 81 are solder-bonded to the plurality of rear-surface-side electrodes 43 at the same time, and thus the second substrate 21 is connected to the first substrate 11. Through the above-described process, the wiring substrate 10 is fabricated.

Therefore, the following effects can be achieved according to the present embodiment.

(1) In the wiring substrate 10 of the present embodiment, the projecting piece 83 projects from the outer peripheral surface 84 at the center portion, in the height direction, of the columnar terminal 81 (columnar terminal body 82). Therefore, when the columnar terminal 81 is bonded onto the main-surface-side electrode 65, the lower end portion of the columnar terminal 81 is immersed into the heated and melted solder portion 80 (solder paste 98). Then, due to influence of the surface tension of the liquid-phase solder or the like, the columnar terminal 81 changes its posture to maintain its weight balance. As a result, the columnar terminal 81 stands upright by itself. Further, since the projecting piece 83 projects from the outer peripheral surface 84 of the columnar terminal body 82, the upper end of the liquid-phase solder portion 80 is prevented from extending upward beyond the projecting piece 83 when the columnar terminal 81 is bonded onto the main-surface-side electrode 65. As a result, the projecting piece 83 is reliably supported by the solder portion 80. Further, since the columnar terminal 81 has a shape vertically symmetrical about the projecting piece 83, the weight balance of the columnar terminal 81 is further improved. The above configuration makes the columnar terminal 81 stand upright more easily. That is, even when the pitch of adjacent terminals is reduced along with downsizing of the wiring substrate 10, since the columnar terminals 81 that are easy to stand upright are used as terminals, it is possible to yield the wiring substrate 10 that can be easily connected to the second substrate 21 via the columnar terminals 81.

(2) In the present embodiment, the lower end surface 86 of the columnar terminal body 82 as a component of the columnar terminal 81 and the surface of the main-surface-side electrode 65 on the first substrate 11 are spaced apart from each other. Therefore, the gap between the lower end surface 86 of the columnar terminal body 82 and the surface of the main-surface-side electrode 65 can be reliably filled with the solder portion 80. As a result, the area of contact between the columnar terminal body 82 and the solder portion 80 and the area of contact between the main-surface-side electrode 65 and the solder portion 80 are increased, whereby the bonding strength between the main-surface-side electrode 65 and the columnar terminal 81 is increased. Further, in the present embodiment, the upper end surface 85 of the columnar terminal body 82 and the surface of the rear-surface-side electrode 43 on the second substrate 21 are spaced apart from each other. Therefore, the gap between the upper end surface 85 of the columnar terminal body 82 and the surface of the rear-surface-side electrode 43 can be reliably filled with the solder portion 39. As a result, the area of contact between the columnar terminal body 82 and the solder portion 39 and the area of contact between the rear-surface-side electrode 43 and the solder portion 39 are increased, whereby the bonding strength between the rear-surface-side electrode 43 and the columnar terminal 81 can be increased. Thus, the connection strength between the first substrate 11 and the second substrate 21 is increased, thereby enhancing reliability of the wiring substrate 10.

The present embodiment may be modified as described below.

In the columnar terminal 81 of the present embodiment, the projecting piece 83 is provided over the entire circumference of the outer peripheral surface 84 of the columnar terminal body 82. However, the projecting piece may not be formed over the entire circumference of the outer peripheral surface of the columnar terminal body. For example, like a columnar terminal 121 shown in FIG. 13, a plurality of projecting pieces 122 may be arranged at equal intervals along the circumferential direction of the columnar terminal body 123.

In the columnar terminal 81 of the above embodiment, the projecting piece 83 is formed integrally with the columnar terminal body 82 at the outer peripheral surface 84 of the columnar terminal body 82. However, like a columnar terminal 131 shown in FIG. 14, a projecting piece 132 may be formed as a component separable from a columnar terminal body 133 at an outer peripheral surface 134 of the columnar terminal body 133.

While the lower end surface 86 of the columnar terminal body 82 as a component of the columnar terminal 81 and the surface of the main-surface-side electrode 65 on the first substrate 11 are spaced apart from each other in the above embodiment, these surfaces may be in contact with each other. Likewise, while the upper end surface 85 of the columnar terminal body 82 and the surface of the rear-surface-side electrode 43 on the second substrate 21 are spaced apart from each other in the above embodiment, these surfaces may be in contact with each other.

The columnar terminals 81 may be formed by a method other than the method of the above embodiment. For example, each columnar terminal 81 may be formed by, with an end portion of a columnar member to be the columnar terminal body 82 being held by a chuck, performing cutting work with a shaping tool attached to a lathe. Alternatively, each columnar terminal 81 may be formed by sandblast or polishing.

The wiring substrate 10 according to the above embodiment is a wiring substrate including the first substrate 11 and the second substrate 21. However, a wiring substrate including only the first substrate 11 may be applied as a wiring substrate of the present invention.

The wiring substrate 10 of the above embodiment is a wiring substrate of a POP structure formed by stacking two semiconductor packages (first substrate 11 and second substrate 21). However, the present invention may be applied to a wiring substrate of another structure. For example, a wiring substrate of a structure formed by stacking a semiconductor package (first substrate) and an IC chip (second substrate) may be applied as a wiring substrate of the present invention.

Next will be given technical ideas that can be understood from the above-described embodiment.

(1) The wiring substrate described as the above means 1 or 2, wherein the projecting piece extends along the circumferential direction of the columnar terminal body.

(2) The wiring substrate described as the above means 1 or 2, wherein the width of the projecting piece is reduced outward in the radial direction of the columnar terminal body.

(3) The wiring substrate described as the above means 1 or 2, wherein the front end portion of the projecting piece has a curved surface.

(4) The wiring substrate described as the above means 1 or 2, wherein the connection portion between the projecting piece and the columnar terminal body has a curved surface.

(5) The wiring substrate described as the above means 1 or 2, wherein the solder resist layer having openings whose inner diameter is set to be larger than the maximum diameter of the columnar terminals is formed on the substrate main surface.

(6) The wiring substrate according to the technical idea of (5), wherein the height of the columnar terminal body is smaller than the inner diameter of the openings of the solder resist layer.

(7) The wiring substrate described as the above means 1 or 2, wherein the maximum diameter of the columnar terminal is set to be smaller than the maximum diameter of the electrode.

(8) The wiring substrate described as the above means 1 or 2, wherein the ratio between the height of the columnar terminal body and the outer diameter thereof is within a range from 1:1 to 3:1.

(9) The wiring substrate described as the above means 1 or 2, wherein the solder portion projects from the electrode, and the upper end thereof extends to the projecting piece.

(10) The wiring substrate described as the above means 1 or 2, wherein the columnar terminal body and the projecting piece are made of copper.

(11) The wiring substrate manufacturing method described as the above means 3, wherein, in the solder paste supplying step, supply of the solder paste is performed by printing.

(12) The wiring substrate manufacturing method described as the above means 3, wherein, in the columnar terminal arrangement step, the plurality of columnar terminals are inserted into the columnar terminal insertion holes of the positioning jig, whereby the plurality of columnar terminals are disposed on the corresponding electrodes.

(13) A method of manufacturing columnar terminals used in a wiring substrate including a first substrate to be connected to a second substrate, including: a columnar member preparation step of preparing columnar members made of a conductive material; and a projecting piece formation step of compressing each columnar member in its axial direction to make a projecting piece project from an outer peripheral surface of the columnar member.

### DESCRIPTION OF REFERENCE NUMERALS

10: wiring substrate
11: first substrate
12: substrate main surface
21: second substrate
57: solder resist layer
59: opening
65: main-surface-side electrode as electrode
80: solder portion
81, 121, 131: columnar terminal
82, 123, 133: columnar terminal body
83, 122, 132: projecting piece
84, 134: outer peripheral surface of columnar terminal body
98: solder paste
A1: outer diameter of columnar terminal body
H1: height of columnar terminal body

What is claimed is:

1. A wiring substrate comprising:
a first substrate for connection to a second substrate, the first substrate including a substrate main surface and a plurality of electrodes disposed on the substrate main surface; and
a plurality of columnar terminals to be solder-bonded to the second substrate, the columnar terminals bonded onto the plurality of electrodes via solder portions, wherein
each of the columnar terminals includes a columnar terminal body made of a conductive material, and a projecting piece that projects from an outer peripheral surface of the columnar terminal body at a center portion, in a height direction, of the columnar terminal body.

2. The wiring substrate according to claim 1, wherein
each of the columnar terminals has a shape vertically symmetrical about the projecting piece.

3. The wiring substrate according to claim 1, wherein
the projecting piece is provided over an entire circumference of the outer peripheral surface of the columnar terminal body.

4. The wiring substrate according to claim 1, wherein
the projecting piece is integrally formed with the columnar terminal body at the outer peripheral surface of the columnar terminal body.

5. The wiring substrate according to claim 1, wherein
the columnar terminal body has a height and an outer diameter, and the height is 1.0 times or more and 3.0 times or less the outer diameter.

6. A method of manufacturing the wiring substrate according to claim 1, comprising:
a substrate preparation step of preparing the first substrate having the plurality of electrodes disposed on the substrate main surface;
a solder paste supplying step of supplying a solder paste onto the plurality of electrodes;
a columnar terminal arrangement step of arranging the columnar terminals on the electrodes to which the solder paste has been supplied; and
a reflow step of heating and melting the solder paste to immerse at least a portion of each of the columnar terminals in the solder paste and to make each of the columnar terminals stand upright.

7. The method according to claim 6, wherein
the substrate main surface is covered with a solder resist layer, and the plurality of electrodes are exposed through openings that penetrate the solder resist layer in a thickness direction of the solder resist layer, and
in the solder paste supplying step, the solder paste is supplied into the openings.
